(19) United States
(12) Patent Application Publication
(10) Pub. No.: US 2024/0276742 A1
(43) Pub. Date: Aug. 15, 2024

(54) SEMICONDUCTOR THIN FILM, METHOD FOR MANUFACTURING THE SAME AND STRETCHABLE ELECTRODE, ORGANIC THIN FILM TRANSISTER, ELECTRONIC DEVICE COMPRISING THE SAME

(71) Applicant: UNIVERSITY-INDUSTRY COOPERATION GROUP OF KYUNG HEE UNIVERSITY, Yongin-si (KR)

(72) Inventors: Jin Young OH, Anyang-si (KR); Minwoo JEONG, Gwangmyeong-si (KR); Min Hyouk KIM, Pyeongtaek-si (KR)

(21) Appl. No.: 18/390,130

(22) Filed: Dec. 20, 2023

(30) Foreign Application Priority Data
Feb. 8, 2023 (KR) 10-2023-0016955
Oct. 17, 2023 (KR) 10-2023-0138900

(51) Int. Cl. H10K 10/46; C23C 16/40; H10K 77/10

(52) U.S. Cl. CPC H10K 10/46; C23C 16/40; H10K 77/111

(57) ABSTRACT

The present invention relates to a semiconductor film including a stretchable semiconductor thin film including a first resin and a second resin and a noble metal layer deposited on the stretchable semiconductor thin film, wherein the first resin includes a structural unit represented by Chemical Formula 1A and/or Chemical Formula 1B, and the second resin includes polydimethylsiloxane, polyurethane, and/or structural units represented by Chemical Formula 2 to Chemical Formula 5, a method of manufacturing the same, a stretchable electrode including the semiconductor film, an organic thin film transistor including the stretchable electrode, and an electronic device including the organic thin film transistor.

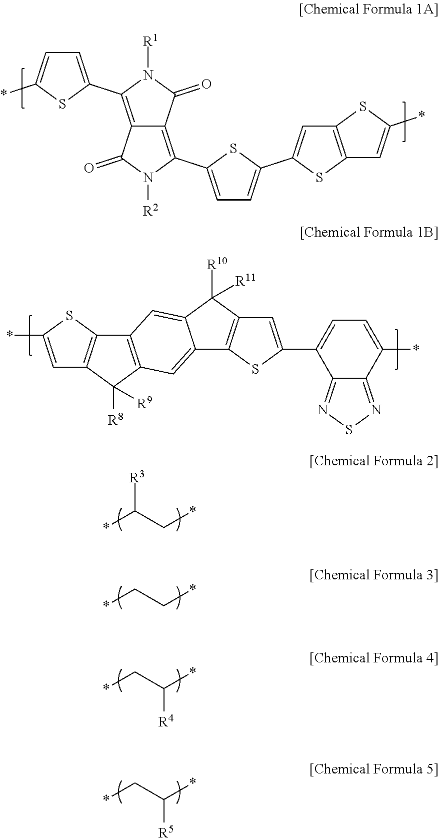

(In Chemical Formula 1A, Chemical Formula 1 B and Chemical Formula 2 to Chemical Formula 5, each substituent is as defined in the specification.)

### BACKGROUND OF THE INVENTION

### (a) Field of the Invention

The present invention relates to a semiconductor film, a method of manufacturing the same, a stretchable electrode including the same, an organic thin film transistor, and an electronic device.

### (b) Description of the Related Art

With the rapid development of biointegrated electronics, as devices are required to have a stretchable form like skin, research on providing stretchable electronic components for them has been much made. Transistors are known to be the most essential switching components in the electronics, but there are still limitations in fabricating stretchable transistors, because all materials that make up the stretchable transistors, such as semiconductors, conductors, and dielectric materials, should be mechanically stretchable materials with high strain compliance and biocompatibility,

Among them, stretchable electrodes for OTFT (organic thin film transistors) are limitedly researched and reported despite its importance.

In general, electrodes in stretchable OTFT, which play a key role of injecting a current into semiconductors, require appropriate work function, stretchability, durability, etc. As the stretchable electrodes of the stretchable OTFT, SWCNT (single-wall carbon nanotubes) with a high work function and appropriate electrical resistance, of which the network structure well maintains electrical penetration even under mechanical stress, has been widely used. However, because SWCNT is toxic in terms of biocompatibility and may cause inflammatory responses, malignant transformation, deoxyribonucleic acid damage, and mutations, feasibility of its use in the field of biomaterials research is still debated. Poly(3,4-ethylenedioxythiophene): poly(styrenesulfonate) (PEDOT:PSS) is considered as another material for the stretchable electrodes. A method of incorporating stretchability into PEDOT:PSS electrodes includes mixing a plasticizer with PEDOT:PSS or blending newly designed PEDOT:PSS with an elastomer. PEDOT:PSS has advantages for OTFT in terms of excellent hole injection, but its use in future bioelectronic applications may be limited due to inherent air instability according to oxidation and relatively low electrical conductivity.

Recently, noble metal deposition through various methods such as physical vapor deposition, ion implantation and chemical reduction has been proposed for stretchable and soft electrodes. Accordingly, a microcrack-based noble metal film on an insulating elastomer such as PDMS and SEBS has been reported as alternative stretchable electrodes for an organic electrochemical transistor (OECT) and OTFT. A microcrack gold (Au) film on the elastomer maintains a conductive path, while releasing stress applied thereto, and thus may work as stretchable electrodes but has a problem such as microscale morphological instability against continuous changes in electrical resistance and deformation. In addition, the microcrack-based stretchable electrodes have another serious drawback of poor adhesion, which may lead to delamination under repeatable mechanical deformation. The adhesion against omnidirectional deformation in the bioelectronics, in order to minimize foreign body sensation when in contact with human skin, should be considered as another important requirement for the stretchable electrodes. The aforementioned studies did not consider peeling deformation and have not yet reached a technology level considering mechanical durability thereof for stretchable semiconductor devices.

### SUMMARY OF THE INVENTION

The present invention provides a mechanically robust stretchable semiconductor metallization based on a metal-elastic (stretchable) semiconductor mixture to overcome the above limitations.

Another purpose is to present materials in the best condition considering conductivity and cost, which are important elements for commercially available industrial use.

An example embodiment provides a semiconductor film including a stretchable semiconductor thin film including a first resin and a second resin and a noble metal layer deposited on the stretchable semiconductor thin film, wherein the first resin includes a structural unit represented by Chemical Formula 1A and/or Chemical Formula 1B, and the second resin includes Chemical Formula 2 to Chemical Formula 5.

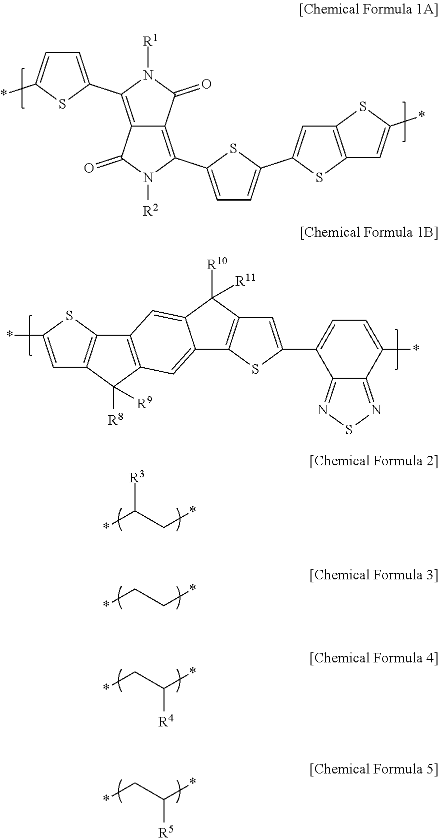

In Chemical Formula 1A, Chemical Formula 1B, and Chemical Formula 2 to Chemical Formula 5,
R¹, R², and R⁴ are each independently a substituted or unsubstituted C1 to C20 alkyl group,
R³ and R⁵ are each independently a substituted or unsubstituted C6 to C20 aryl group, and
R⁸ to R¹¹ are each independently a substituted or unsubstituted C11 to C20 alkyl group.

R¹ and R² may be the same as each other.

R¹ and R² may be represented by Chemical Formula 1-1.

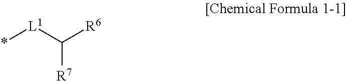

In Chemical Formula 1-1,
L¹ is a substituted or unsubstituted C1 to C20 alkylene group,
R⁶ and R⁷ are each independently a substituted or unsubstituted C1 to C10 alkyl group.

R⁸ to R¹¹ may be the same as each other.

R⁸ to R¹¹ may be each an unsubstituted C11 to C20 alkyl group.

The first resin may have a weight average molecular weight of greater than or equal to 100,000 g/mol.

A number of moles of the structural units represented by Chemical Formula 2 and Chemical Formula 5 and a number of moles of structural units represented by Chemical Formula 3 and Chemical Formula 4 may be 10 to 70:30 to 90.

The noble metal may include silver (Ag).

The semiconductor film further includes a noble metal oxide layer between the stretchable semiconductor thin film and the noble metal layer.

A thickness of the noble metal layer may be thinner than a thickness of the noble metal oxide layer, and a thickness of the noble metal oxide layer may be thinner than a thickness of the stretchable semiconductor thin film.

According to an embodiment, a method of manufacturing a semiconductor film includes preparing a stretchable semiconductor thin film including a first resin and a second resin; and depositing a noble metal on the stretchable semiconductor thin film, wherein the deposition rate is less than or equal to 2 Å/s.

The first resin, second resin, and precious metal may be the same as described above.

According to another embodiment, a stretchable electrode including the semiconductor film is provided.

The stretchable electrode may have a thickness of less than or equal to 50 nm.

Another embodiment provides an organic thin film transistor including the stretchable electrode.

Another embodiment provides an electronic device including the organic thin film transistor.

The electronic device may be a wearable electronic device.

According to an embodiment of the present invention, by vapor deposition of noble metals (silver, Ag) on a stretchable semiconductor thin film, it is possible to implement a stretchable electrode that exhibits excellent charge injection characteristics, adhesion, long-term oxidation stability, and excellent electrical property maintenance under tensile strain, the performance of next-generation stretchable wearable electronic devices including such stretchable electrodes can be greatly improved.

### BRIEF DESCRIPTION OF THE DRAWINGS

FIG. 1 is a photograph showing a change in surface nanomorphology before (bottom) and after (top) metallization of the semiconductor film.

FIG. 2 is a transfer curve of an organic field effect transistor (OFET) according to the type of transition metal.

FIG. 3 is a graph showing the change in resistance depending on the channel length of an OFET with Ag electrodes.

FIG. 4 is a graph showing the Schottky barrier of an OFET with Ag electrodes.

FIG. 5 is a graph of the XPS spectrum in the range of 360 to 376 eV depending on an etching time at the interface between the noble metal layer and the stretchable semiconductor thin film.

FIG. 6 is a graph showing the Ag atomic fraction and Ag oxide/Ag ratio of the Ag film according to etching time.

FIG. 7 is a graph showing the change in conductivity according to the thickness of the Ag electrode.

FIG. 8 is a graph showing changes in conductivity and crack formation during tensile strain depending on the thickness of the Ag electrode.

FIG. 9 is a graph showing changes in resistance and crack formation during tensile strain according to Ag electrode deposition rate.

FIG. 10 is a graph showing changes in conductivity of a 50 nm Ag electrode according to repeated tensile strain.

FIG. 11 is a graph showing mechanical plastic deformation of SEBS and Ag metallized DPPT-TT:SEBS/SEBS substrate film after repeated stretching.

FIG. 12 is a graph showing changes in resistance of the Ag electrode according to exposure to air.

FIG. 13 is a photograph and graph evaluating the adhesive force applied when attaching/detaching a commercial adhesive tape.

FIG. 14 is a graph showing changes in conductivity when attaching/detaching a commercial adhesive tape.

FIG. 15 is an XPS depth profiling graph for confirming Ag infiltrated into the stretchable semiconductor thin film.

FIG. 16 is an XPS depth profiling graph for confirming Au infiltrated into the stretchable semiconductor thin film.

FIG. 17 is an XPS depth profiling graph for confirming Cu infiltrated into the stretchable semiconductor thin film.

FIG. 18 is a photograph of a STEM analysis of nanoscale cracks in an Ag electrode due to tensile strain.

FIG. 19 is a STEM-EDS analysis photo of the surface composition of an Ag electrode at 100% tensile strain.

FIG. 20 is a cross-sectional STEM-EDS analysis photograph for analyzing the interface composition between the noble metal layer and the stretchable semiconductor thin film.

FIG. 21 is a photograph showing the results of Ag metallization evaluation of a stretchable semiconductor thin film (using the first resin including a repeating unit represented by Chemical Formula 6B). (The stretchable semiconductor thin film in other figures uses the first resin including a repeating unit represented by Chemical Formula 6A.)

FIG. 22 is a graph showing changes in electrical performance according to biaxial stretching of a fully stretchable transistor using Ag metallization of a stretchable semiconductor thin film (using a first resin including a repeating unit represented by Chemical Formula 6B). (The stretchable semiconductor thin film in other figures uses the first resin including a repeating unit represented by Chemical Formula 6A.)

FIG. 23 is a graph showing changes in electrical performance of an Ag metallized stretchable semiconductor thin film (using a first resin including a repeating unit represented by Chemical Formula 6B) after attaching/detaching of a commercial adhesive tape. (The stretchable semiconductor thin film in other figures uses the first resin including a repeating unit represented by Chemical Formula 6A.)

FIG. 24 is a device transfer curve graph for each drain voltage of a fully stretchable transistor.

FIG. 25 is a transfer curve for a fully stretchable transistor.

FIG. 26 is an output curve of a fully stretchable transistor.

FIG. 27 is a graph showing changes in electrical performance of a fully stretchable transistor according to tensile strain (tensile direction: parallel and perpendicular to the channel direction).

FIG. 28 is a graph showing changes in electrical performance of a fully stretchable transistor according to repeated tensile strain (tensile direction: parallel and perpendicular to the channel direction).

FIG. 29 is a fully stretchable transistor transfer curve under biaxial tensile strain.

FIGS. 30 and 31 are schematic views showing metallization of a stretchable semiconductor thin film, respectively.

FIG. 32 is a schematic view of tensile deformation of a stretchable electrode.

FIG. 33 is a schematic view of an active matrix array device including a stretchable semiconductor thin film according to an embodiment.

FIG. 34 is an optical micrograph of the detailed structure of the active matrix array.

FIG. 35 is a transfer curve for 25 devices in a 5×5 active matrix array.

FIG. 36 is an output curve of 25 devices in a 5×5 active matrix array.

FIG. 37 is the charge mobility of 25 devices in the active matrix array.

FIG. 38 is a distribution view of charge mobility and on/off characteristics of 25 devices in the active matrix array.

FIG. 39 is the electrical performance reliability indexes of 25 devices in the active matrix array.

FIG. 40 is a graph of elasticity evaluation through a cyclic deformation test of an active matrix array device.

FIG. 41 is a photograph of the performance evaluation of various deformation environments of an active matrix array device.

FIG. 42 is a graph comparing environmental performance of various modifications of an active matrix array device.

FIG. 43 is a graph measuring real-time performance changes of an active matrix array device in various deformation environments.

### DETAILED DESCRIPTION OF THE EMBODIMENTS

Specific structural or functional descriptions of the embodiments according to the concept of the present invention disclosed in this specification are merely illustrative for the purpose of explaining the embodiments according to the concept of the present invention, and embodiments according to the concept of the present invention may be implemented in various forms and are not limited to the embodiments described in this specification.

Since the embodiment according to the concept of the present invention can make various changes and have various forms, the embodiment will be illustrated in the drawings and described in detail in this specification. However, this is not intended to limit the embodiments according to the concept of the present invention to a specific disclosed form, and includes changes, equivalents, or substitutes included in the spirit and technical scope of the present invention.

Terms such as first or second may be used to describe various components, but the components should not be limited by the terms. The above terms are used only for the purpose of distinguishing one component from another component, and for example, without departing from the scope of rights according to the concept of the present invention, a first component may be named a second component, and similarly, the second component may also be named a first component.

When a component is said to be “connected” or “coupled” to another component, it is understood that it may be directly connected to or coupled to the other component, but It should be understood that other components may exist in the middle. On the other hand, when it is mentioned that a component is “directly connected” or “directly coupled” to another component, it should be understood that there are no other components in the middle. Surfaces that describe relationships between components, such as “between” and “immediately between” or “directly adjacent to”, should be interpreted similarly.

The terms used herein are only used to describe specific embodiments and are not intended to limit the invention. Singular expressions include plural expressions unless the context clearly dictates otherwise. In this specification, terms such as “comprise” or “have” are intended to designate the presence of implemented features, numbers, steps, operations, components, parts, or combinations thereof, and it should be understood that this does not exclude in advance the presence or addition of one or more other features, numbers, steps, operations, components, parts, or combinations thereof.

Unless otherwise defined, all terms used herein, including technical or scientific terms, have the same meaning as commonly understood by a person of ordinary skill in the technical field to which the present invention pertains. Terms as defined in commonly used dictionaries should be interpreted as having meanings consistent with the meanings they have in the context of the related technology, and unless explicitly defined herein, it is not to be interpreted in an ideal or overly formal sense. Hereinafter, embodiments will be described in detail with reference to the attached drawings.

A semiconductor film according to an embodiment includes a stretchable semiconductor thin film including a first resin and a second resin and a noble metal layer deposited on the stretchable semiconductor thin film, wherein the first resin includes a structural unit represented by Chemical Formula 1A and/or Chemical Formula 1B, and the second resin includes Chemical Formula 2 to Chemical Formula 5.

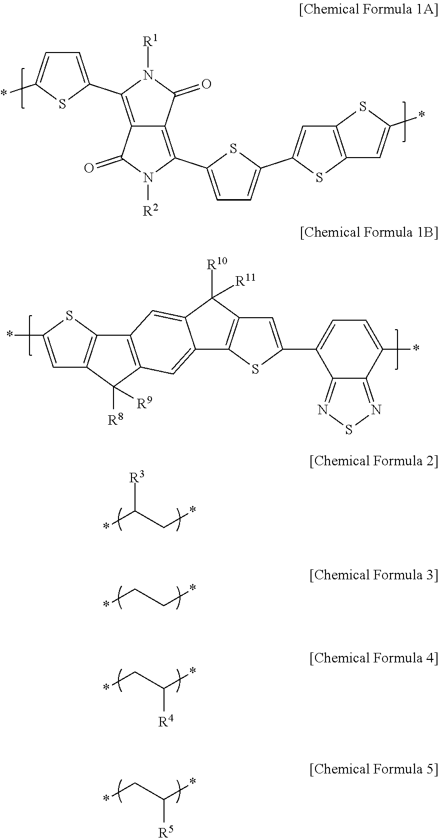

In Chemical Formula 1A, Chemical Formula 1B, and Chemical Formula 2 to Chemical Formula 5,
R¹, R², and R⁴ are each independently a substituted or unsubstituted C1 to C20 alkyl group,
R³ and R⁵ are each independently a substituted or unsubstituted C6 to C20 aryl group, and
R⁸ to R¹¹ are each independently a substituted or unsubstituted C11 to C20 alkyl group.

The semiconductor film may include a noble metal layer deposited on a stretchable semiconductor thin film including the first resin and the second resin, and as described later, after deposition of the noble metal layer, the noble metal penetrates into the stretchable semiconductor thin film due to its unique diffusivity to generate a mixed layer. This results in excellent adhesion between the stretchable semiconductor thin film and the noble metal layer. In addition, in the mixed layer, a natural oxide layer is naturally generated at the interface between the stretchable semiconductor thin film and the noble metal layer, thereby improving the electrical properties and easily achieving metallization of the stretchable semiconductor thin film, which ultimately makes it possible to create electrodes with excellent stretchability, conductivity, adhesion, and durability.

That is, the stretchable semiconductor thin film according to an embodiment has the composition as described above, and it is possible to manufacture a stretchable electrode by depositing a noble metal on the thin film by vapor deposition, and an organic field transistor device including the stretchable electrode may have excellent electrical properties, stretchability, and durability.

For example, in Chemical Formula 1A, R¹ and R² may be the same as each other.

For example, in Chemical Formula 1A, R¹ and R² may be represented by Chemical Formula 1-1.

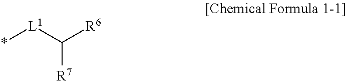

In Chemical Formula 1-1,
L¹ is a substituted or unsubstituted C1 to C20 alkylene group, and
R⁶ and R⁷ are each independently a substituted or unsubstituted C1 to C10 alkyl group.

For example, in Chemical Formula 1B, R⁸ to R¹¹ may be the same as each other.

For example, R⁸ to R¹¹ may each be an unsubstituted C11 to C20 alkyl group.

For example, the first resin may have a weight average molecular weight of greater than or equal to 100,000 g/mol, for example, 100,000 g/mol to 1,000,000 g/mol.

In Chemical Formula 1A, when R¹ and R² are each represented by Chemical Formula 1-1 and the weight average molecular weight of the first resin including the structural unit represented by Chemical Formula 1A is the same as above, or, in Chemical Formula 1B, R⁸ to R¹¹ is each an unsubstituted C11 to C20 alkyl group and the weight average molecular weight of the first resin including the structural unit represented by Chemical Formula 1B is as above, the stretchability of the stretchable semiconductor thin film may be improved.

For example, Chemical Formula 1A may be represented by Chemical Formula 6A (e.g., DPPT-TT, etc.), but is not necessarily limited thereto.

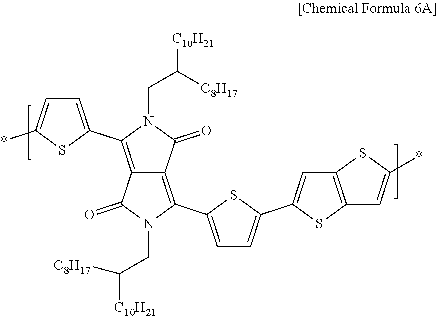

For example, Chemical Formula 1B may be represented by Chemical Formula 6B (e.g., IDT-BT, etc.), but is not necessarily limited thereto.

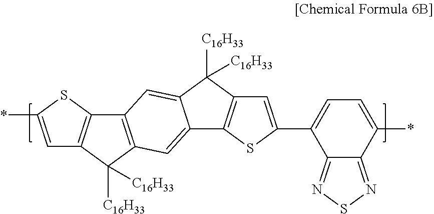

For example, a number of moles of the structural units represented by Chemical Formula 2 and Chemical Formula 5 and a number of moles of structural units represented by Chemical Formula 3 and Chemical Formula 4 may be 10 to 20:80 to 90. That is, the second resin may be represented by Chemical Formula 7 but is not necessarily limited thereto.

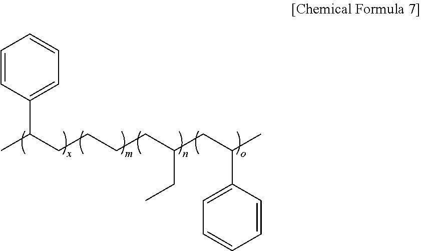

In Chemical Formula 7,
x, m, n, and o are each independently an integer ranging from 1 to 100, provided that x+m+n+0=100.

In Chemical Formula 7, a ratio of (x+0): (m+n) may be 10-70:30-90, for example, 10-20:80-90, for example, 18:82.

The noble metal may include silver (Ag).

TABLE 1

| | Mobility (cm²V⁻¹s⁻¹) |
|---|---|
| silver (Ag) | 0.36 |
| gold (Au) | 0.084 |
| copper (Cu) | 0.003 |

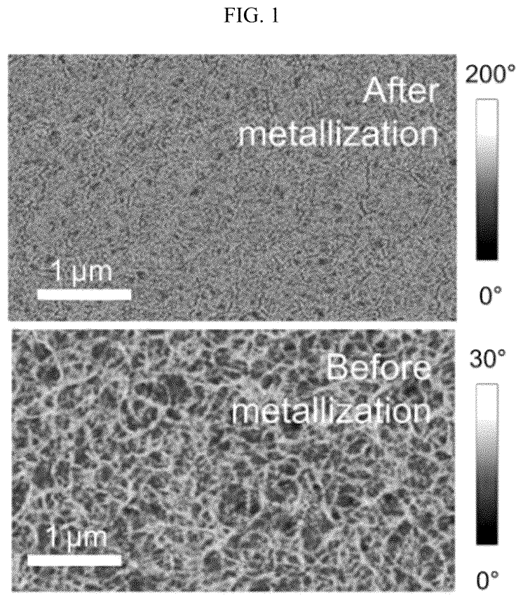

AFM analysis was performed to investigate changes in surface nanomorphology before and after metallization of semiconductor film, and the results are shown in FIG. 1. Referring to FIG. 1, a clear nanofiber structure is continuously formed on the surface of the semiconductor film after metallization of the semiconductor film.

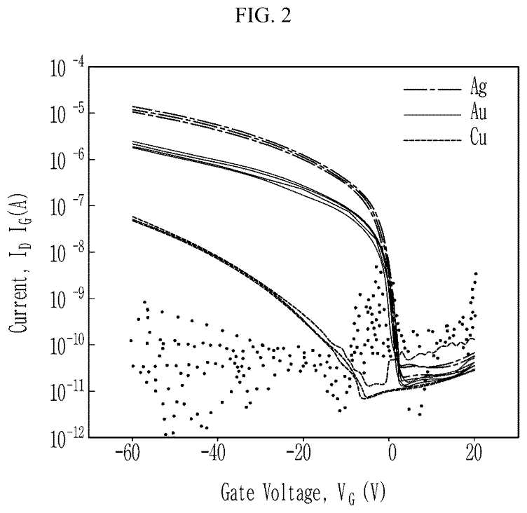

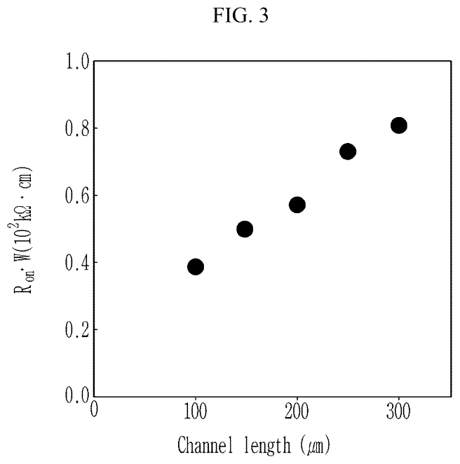

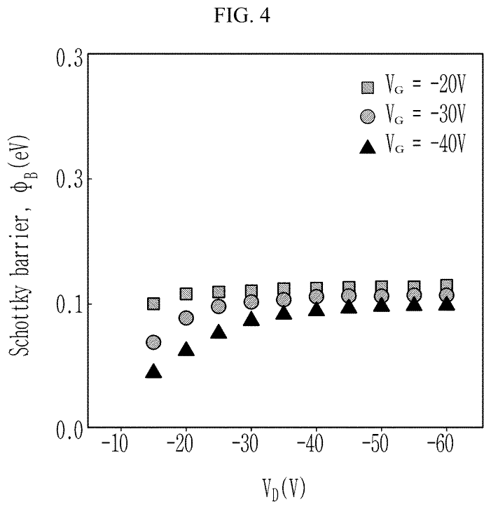

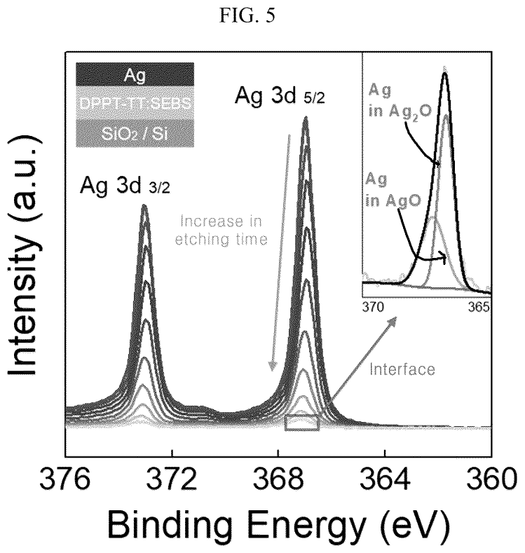

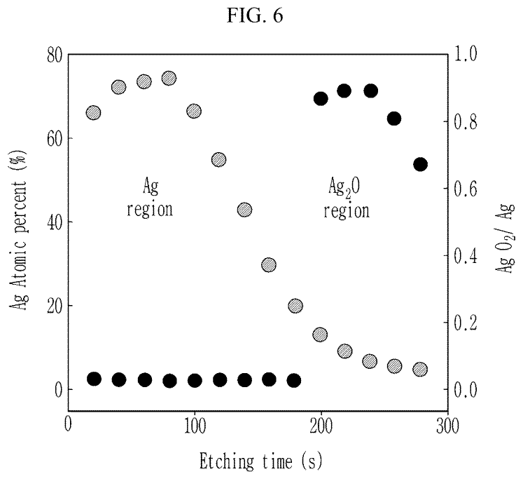

In addition, FIGS. 2 to 6 and Table 1 show data evaluating the charge injection characteristics of OFET devices using Ag electrodes.

In order to verify functionality of Ag-semiconductor metallization as source/drain electrodes, styrene-ethylene-butylene-styrene (SEBS) elastomer and nanofiber-based DPPT-TT (poly(2,5-bis(2-octyldodecyl)-3, OTFT was manufactured and evaluated with a thin film elastic semiconductor composed of 6-di(thiophen-2-yl) diketopyrrolo[3,4-c] pyrrole-1,4-dione-alt-thieno[3,2-b] thiophen)). Interestingly, OTFT has a higher mobility (0.36 cm²/Vs) on Ag than on other noble metals (Cu: 0.003 cm²/Vs and even Au: 0.084 cm²/Vs). Additionally, Ag showed the lowest contact resistance (RC) (0.17 MΩ) among metals (Au, Cu, Ag), showing excellent properties compared to previously reported stretchable CNT and PEDOT:PSS electrodes. The effective hole injection barrier is about 0.1 eV, which is negligible compared to the existing injection barrier of 0.2 eV or more.

In order to gain more insight into the excellent hole injection, X-ray photoelectron spectroscopy (XPS) depth profiling is utilized to analyze the compositional changes at the interface between Ag and the polymer semiconductor in the depth direction, and the results found that there was an Ag native oxide layer. It can be seen that (AgxO) with a high work function (ΦW=5.2 eV) is formed (HOMO=5.04 eV) at the interface between Ag and the elastic semiconductor film, and the presence of AgxO results in the lowest contact resistance (RC) and Ag electrodes with an effective injection barrier (ΦB) can be implemented.

That is, the semiconductor film may further include a noble metal oxide layer between the stretchable semiconductor thin film and the noble metal layer.

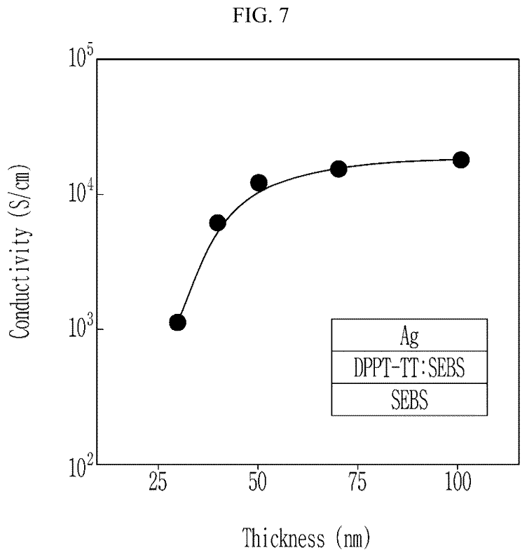

FIGS. 7 to 11 show electrical conductivity and tensile strain stability evaluation data according to the thickness and deposition rate of the Ag electrode.

The electrical conductivity of Ag metallization can be optimized as a function of thickness, and it can be seen that as the thickness increases, the electrical conductivity rapidly increases to 12,532+409 S/cm (50 nm) and then is maintained. These results indicate that a continuous Ag thin film is formed after deposition of approximately 50 nm.

It can also be seen that the mechanical stretchability of Ag metallization is greatly affected by thickness. At a thickness of 50 nm or less, the Ag electrode almost preserves its initial resistance even at 100% strain without an increase in resistance, but at thicknesses above that, a rapid change in resistance due to changes in tension is observed. Microscale crack morphology of 50 nm Ag metallization on elastic semiconductor under initial and 100% strain conditions formed a phenomenon consistent with resistance change, and a fraction of the crack area for the Ag metallized film was quantified as shown in the figure, and it can be confirmed that cracks rarely occur below 50 nm.

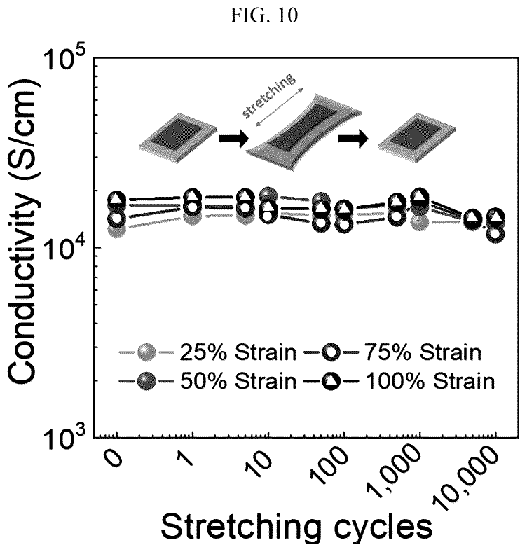

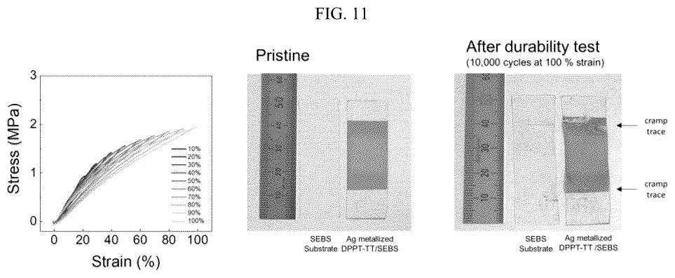

In particular, by confirming through FIG. 11 that mechanical plastic deformation of the device itself does not occur, it can be seen that the data on the change in electrical conductivity due to repeated stretching in FIG. 10 is not affected by this.

Ultimately, in order to balance electrical conductivity and mechanical stretchability, 50 nm was found to be the optimal thickness of Ag metallization, which consists of a metal-elastic semiconductor mixed region and a pure metal region. That is, as will be described later, the stretchable electrode including a semiconductor film according to an embodiment may have a thickness of 50 nm or less.

According to another embodiment, a method of manufacturing a semiconductor film includes preparing a stretchable semiconductor thin film including a first resin and a second resin; and depositing a noble metal on the stretchable semiconductor thin film, wherein the deposition rate is less than or equal to 2 Å/s. The first resin, second resin, and noble metal may be as described in this specification.

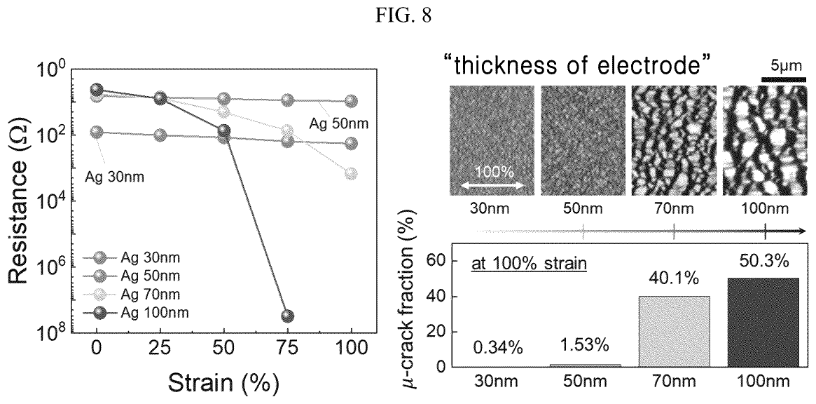

The deposition rate of Ag is an important process parameter that affects the crack morphology and resistance changes of the metallization under strain, it can be seen from FIG. 8 that while faster deposition rates above 3 Å/s make it sensitive to metallization deformation with a large crack area fraction (>48%), metallization at deposition rates below 2 Å/s has relatively insensitive resistance to strain, with a negligible crack area fraction of less than 2% at up to 100% strain. These results indicate that the formation of metal-elastic semiconductor intermixing can be affected by deposition rate. The faster the deposition rate, the faster the metal film is formed on the surface because the newly deposited Ag atoms do not diffuse inward but are consumed in thin film growth, and slower deposition rates are more likely to form metal-elastic semiconductor mixed regions, resulting in higher initial resistance and gradually increased resistance to deformation due to thinner metal layers. Therefore, a moderate deposition rate (2 Å/s) for metallization is applied for mechanically robust stretchable metallization, striking a balance between the metal-elastic semiconductor mixing for adhesion and the metal layer for resistance.

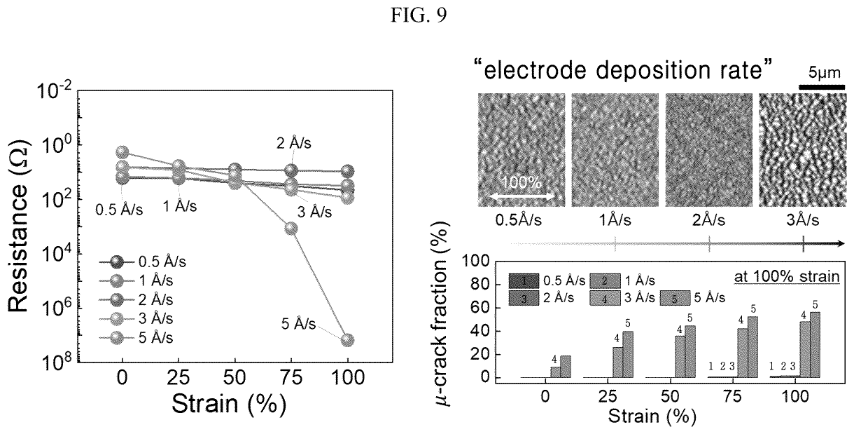

Additionally, to evaluate the tensile durability of Ag metallized electrodes (50 nm), the electrical resistance was tracked during 10,000 tensions with strain amplitudes of 25, 50, 75, and 100%, respectively, and thus referring to FIG. 9, the Ag metallized electrode almost maintains its initial electrical resistance without plastic deformation even after severe multiple stretching.

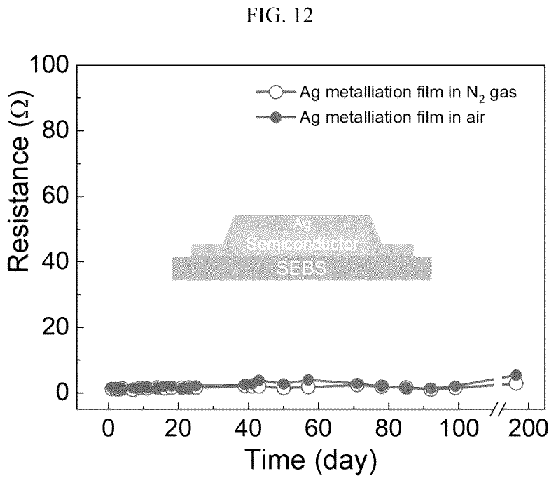

FIG. 12 shows long-term oxidation stability evaluation data of Ag electrodes according to air exposure.

In order to evaluate the long-term oxidation stability of Ag metallization on elastomeric semiconductor films, resistance changes were compared in a nitrogen atmosphere and ambient atmosphere, and the results showed that the initial resistance was maintained at the same level as when stored in a glove box for more than half a year (193 days) in air.

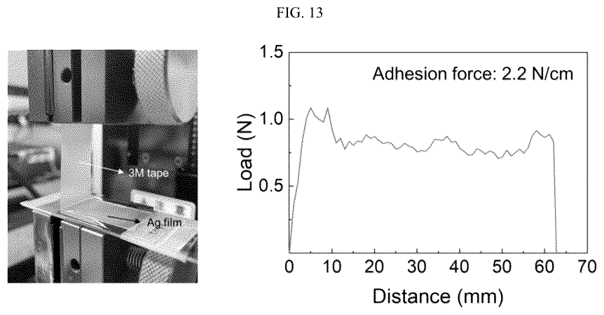

FIG. 13 shows evaluation data on the adhesive force applied when attaching/detaching a commercial adhesive tape, and it can be seen that a force of approximately 2.2 N/cm is applied during detachment.

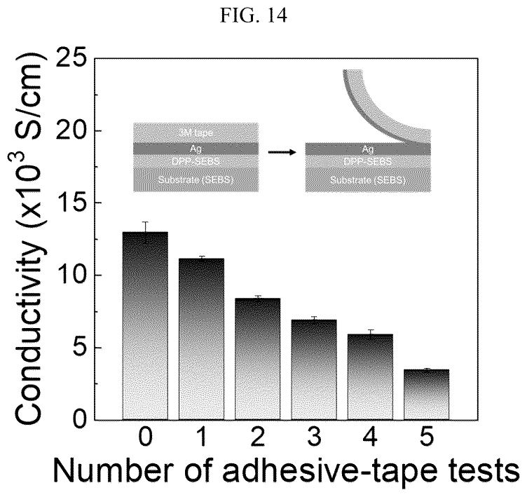

FIG. 14 shows adhesion evaluation data according to the change in conductivity when attaching and detaching the adhesive tape to the Ag electrode.

In order to evaluate adhesive durability of the Ag metallization electrode under harsh conditions, a peel wear test was performed by using a commercially available 3M tape (3M 810 tape, adhesion: 2.2 N/cm). The Ag metallization electrode maintained high electrical conductivity without serious peeling even after five times separating the tape therefrom. Because a noble metal forms a physical bond rather than a chemical bond with an organic polymer, even though a deposited novel metal film is known to be easily peeled off from the elastic organic polymer, the Ag metallization in the present invention exhibited unprecedented adhesive durability.

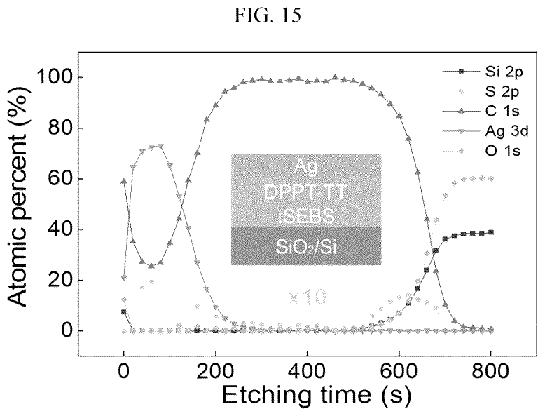

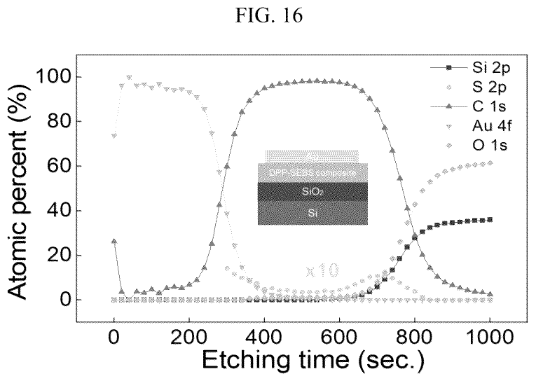

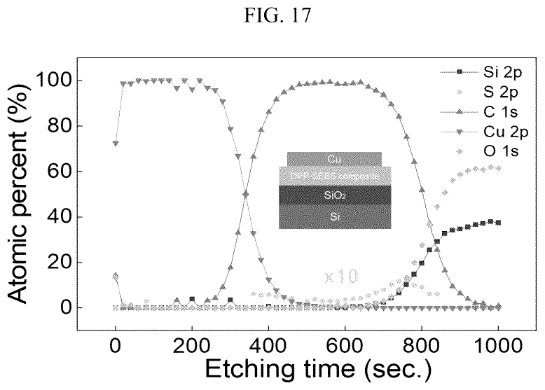

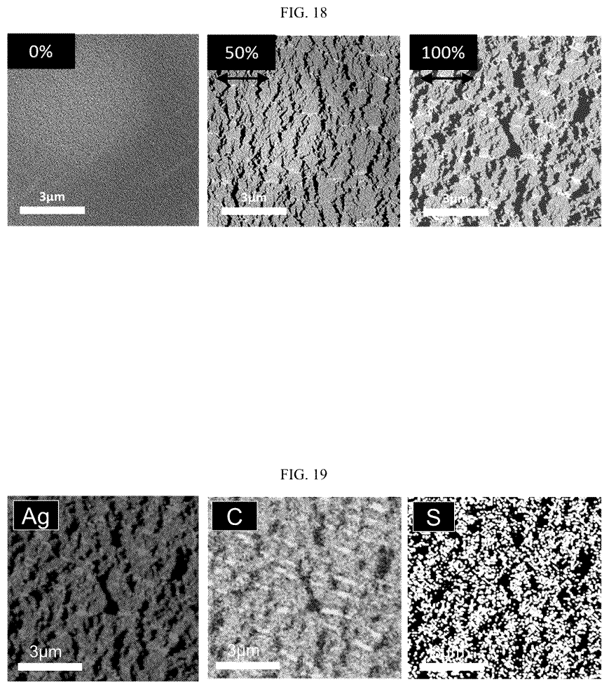

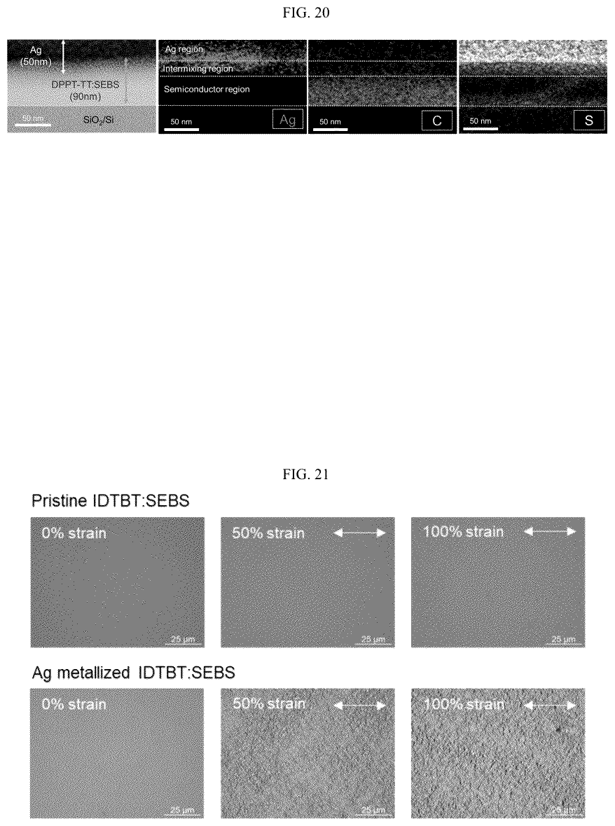

FIGS. 15 to 20 show evaluation data for the formation of an intermediate layer at the metal-elastic polymer semiconductor interface.

In order to collect direct data for the presence of metal-elastic semiconductor mixing, an XPS depth profiling analysis of the metallization film was performed. In the Ag metallization, a metal-elastic semiconductor mixed region (an atomic fraction in the middle of a metal region: Ag: 73.1% and C_{Ag}: 26.9%, DPPT-TT:SEBS composite) was observed. Compared with other noble metals, Ag is known to have a high diffusion coefficient in a polymer, and Ag, Au and Cu respectively have a relative surface diffusion coefficient of 100, 2, and 1 at room temperature, which are higher than those of the other noble metals.

Referring to FIGS. 15 to 17, when the XPS depth profiling analysis results was used to determine the presence or absence of infiltrated Ag, Au, and Cu, Ag was confirmed, but Au and Cu were not almost infiltrated into the semiconductor film, which may be one of the reasons supporting that in the present invention, it is desirable for the noble metal to include silver (Ag), that is, desirable to use an Ag electrode.

In order to further examine strong adhesion of the Ag film deposited on the elastic semiconductor polymer, a scanning transmission electron microscope (STEM) was used to examine nanoscale morphology of the tensile-strained Ag film. In the STEM images of the Ag film with a thickness of 50 nm at various strains (0%, 50%, and 100%), the pure Ag film (strain 0%) exhibited the uniform surface, but when the strain increased to 50%, the film began to tear and exhibited nano-sized cracks instead of peeling off as a method of releasing external stress. When the strain further increased to 100%, the cracks further expanded, but the Ag film maintained geometric connectivity without significant propagation of the cracks. As a result of elemental mapping through energy dispersive X-ray spectroscopy (EDS) of the STEM images of the film at the 100% strain state, Ag, sulfur (S) of DPPT-TT, and carbon (C) of DPPT-TT exhibited almost the same spatial distribution as the initial state. This result means that Ag and the semiconductor polymer were not separated but strongly bonded to each other under the stress. Additionally, a result of examining an element distribution on the cross-section in a depth direction through a STEM-EDS analysis, there were three separate layers (top: a 20 nm-thick Ag, middle: a 30 nm-thick Ag-semiconductor, bottom: a 60 nm-thick continuous section). For example, the noble metal layer may thinner than the noble metal oxide layer, and the noble metal oxide layer may be thinner than the stretchable semiconductor thin film.

Resultantly, Ag and the elastic semiconductor turned out to have a very large number of physical bond regions in the mixed layer and formed strong adhesion. Accordingly, the conventional single Ag-polymer structure may contribute to high robustness and conductivity of the Ag metallization in addition to charging for the adhesion.

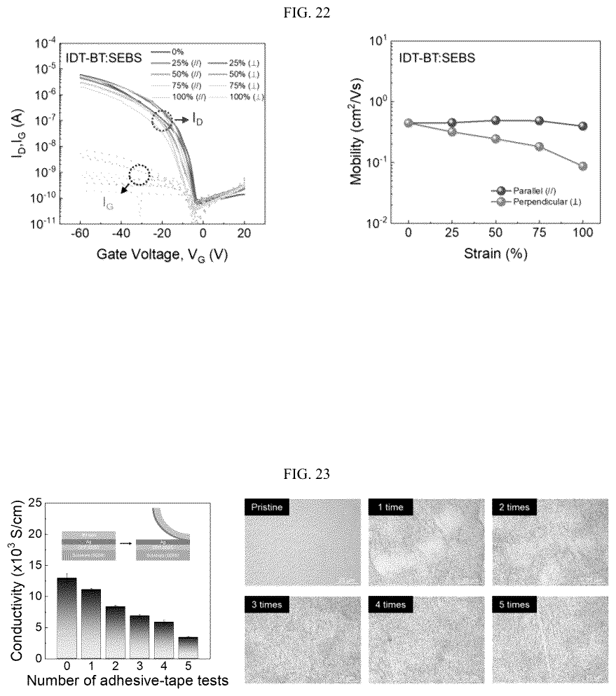

In addition, referring to FIGS. 21 to 23, even though the first resin included the repeating unit represented by Chemical Formula 6B in addition to the repeating unit represented by Chemical Formula 6 Å, the same result was obtained. In particular, FIG. 22 confirmed that performance was stably maintained even after biaxial tensile strain, and FIG. 23 confirmed strong adhesive characteristics.

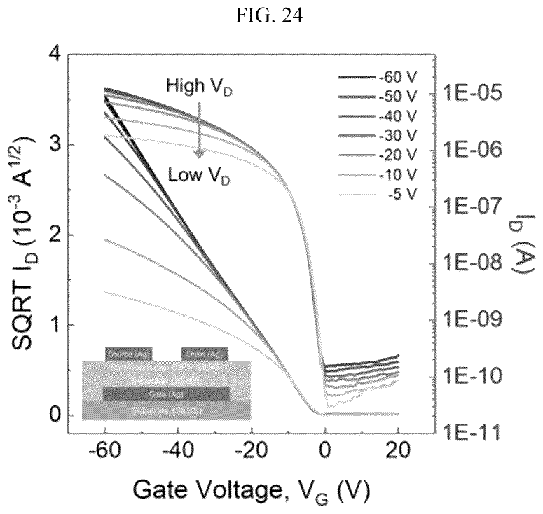

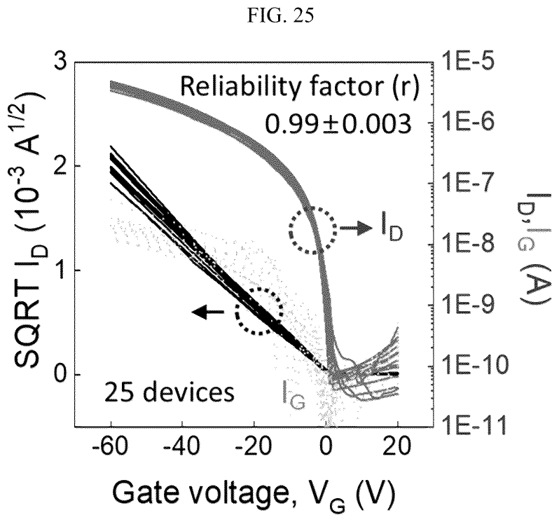

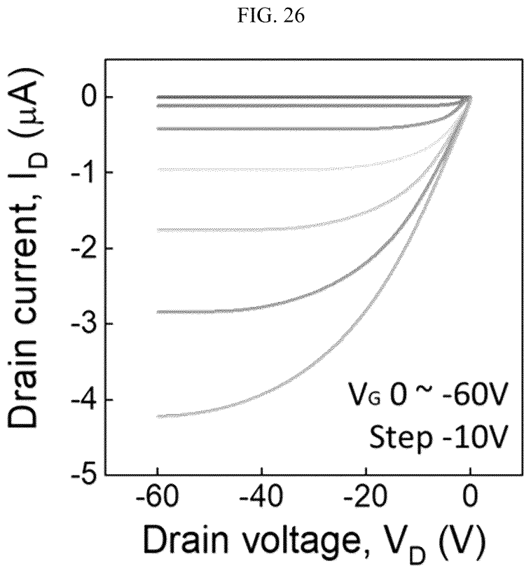

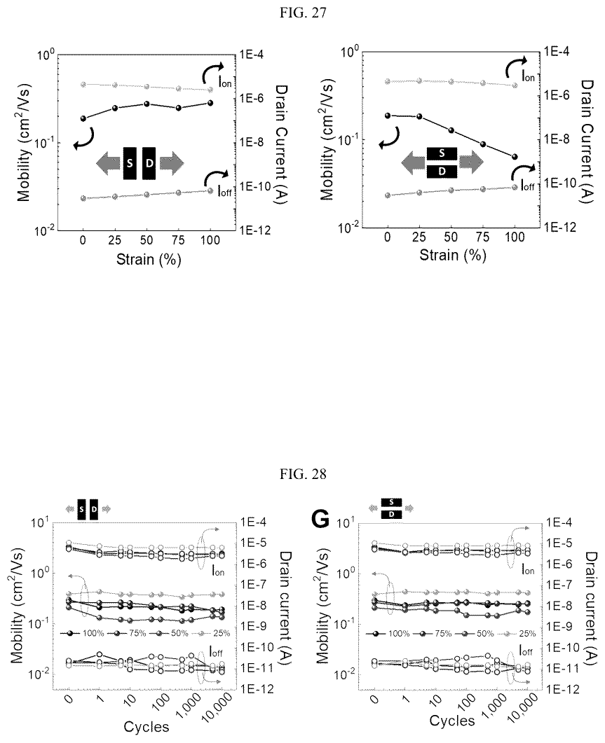

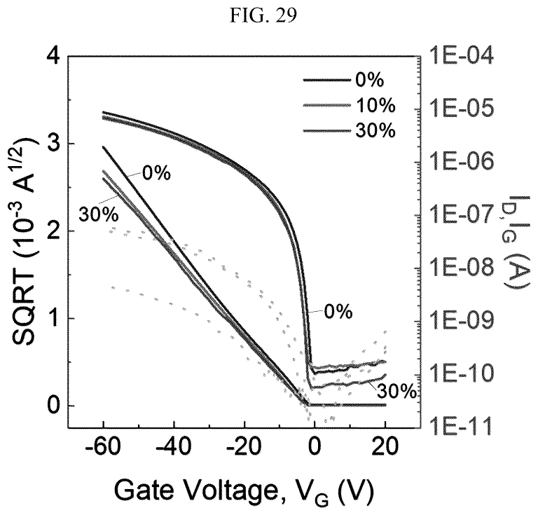

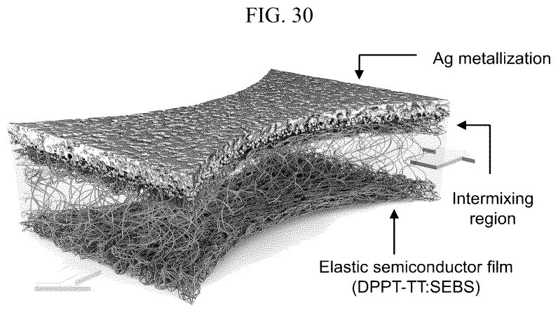

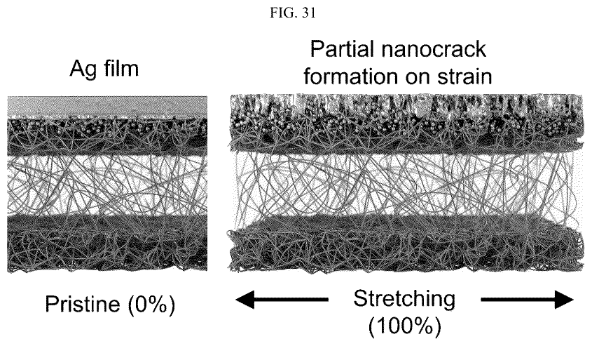

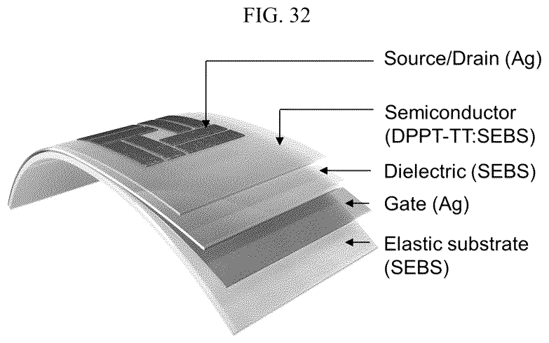

FIGS. 24 to 29 show tensile strain stability evaluation data of a fully stretchable transistor device using the metal-elastic polymer semiconductor metallization.

The stretchable Ag metallization characteristics were applied to manufacture fully stretchable OTFTs at a top contact and a bottom gate with Ag electrodes, DPPT-TT/SEBS nano thin film elastic semiconductors, and SEBS dielectric materials. The 25 manufactured devices had average electric field-effect mobility of 0.99±0.003 and a reliability coefficient of 0.288 cm²/Vs, which confirm the fully stretchable devices were very reliable in terms of charge carrier transport. For example, referring to FIG. 24, the manufactured fully stretchable transistors turned out to stably operate within a drain voltage (−5 V to −60 V) range.

When the device was stretched up to 100% strain at most along a channel length and a width direction, the electric field effect mobility and an on-off ratio were respectively maintained around 0.183 cm²/Vs and 3.94×10⁴. In addition, the fully elastic OTFT devices maintained its initial electrical properties regardless of its tensile direction even under 100% cyclic tensile strain applied 10,000 times or more. The results represent the most severe stretching durability test previously reported for highly reliable elastic OTFTs. In addition, the stretchable OTFTs were confirmed to successfully operate under biaxial strain of 30% at most, while maintaining initial electrical performance.

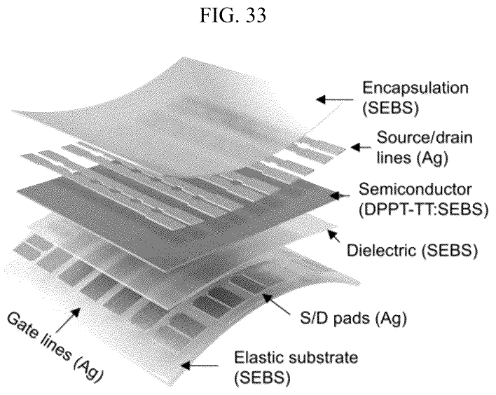

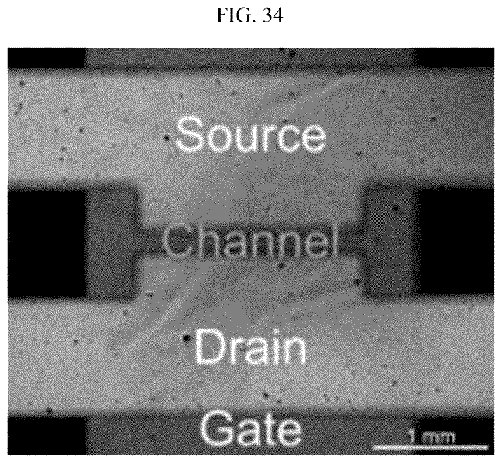

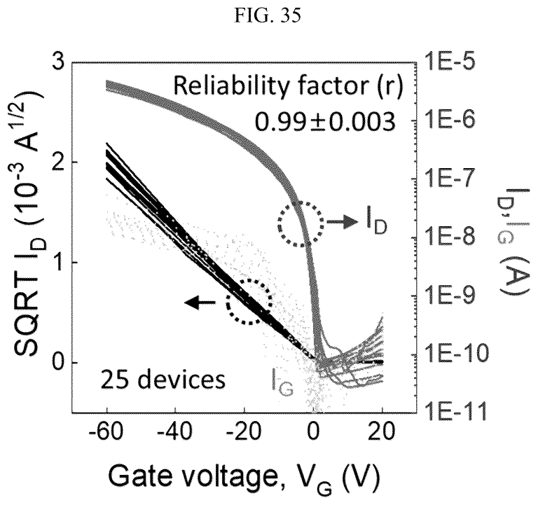

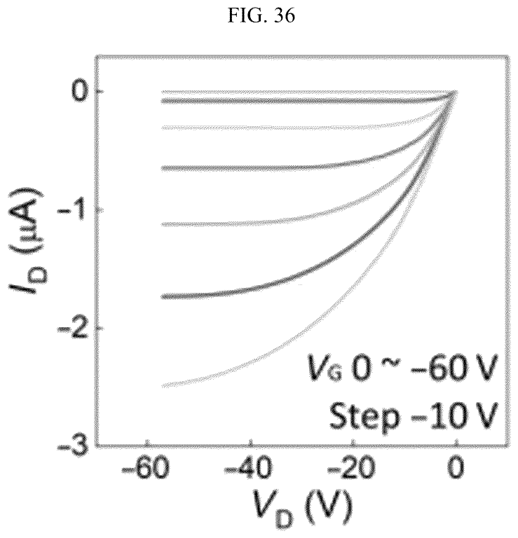

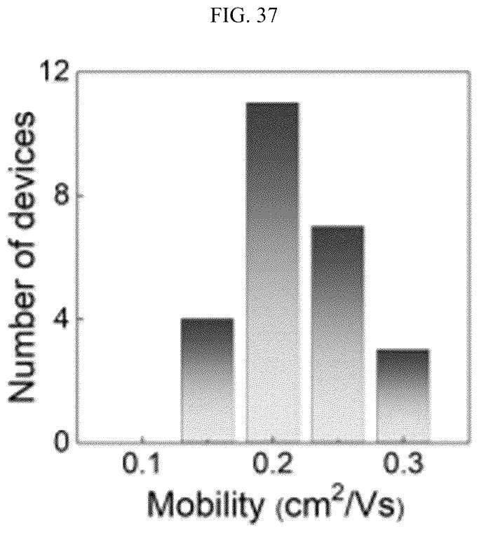

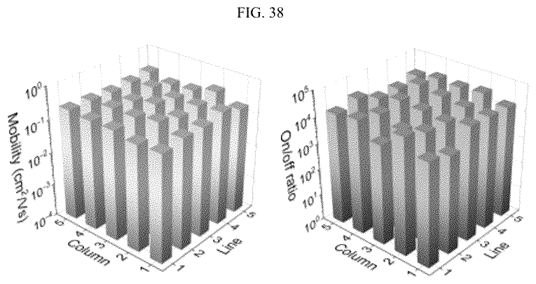

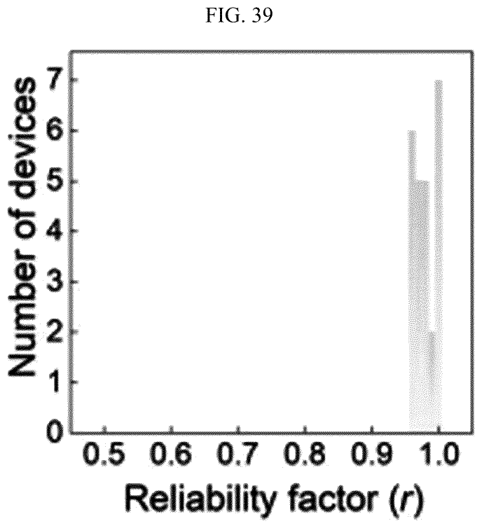

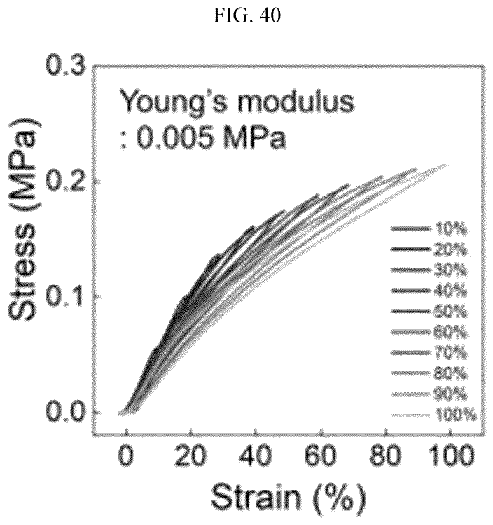

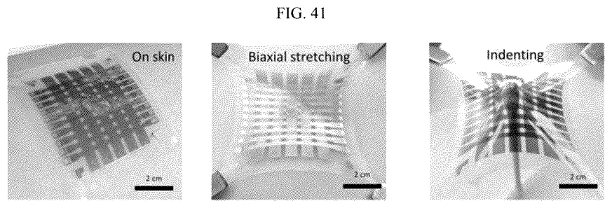

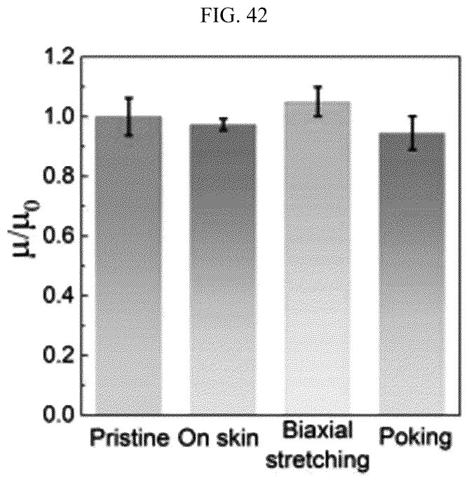

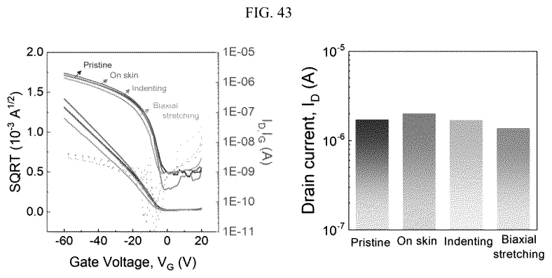

FIGS. 33 and 34 are schematic views respectively showing an active matrix array device including the stretchable semiconductor thin film according to the example and an optical micrograph showing a detailed structure of the active matrix array, and FIGS. 35 to 43 provide experimental data evaluating performance of the active matrix array. Specifically, in order to practically apply the Ag metallization of the stretchable semiconductor film, a 5×5 active matrix array of OTFTs, which was fully stretchable and insensitive to deformation, was manufactured. FIG. 34 shows an optical microscope (OM) image of a detailed structure of the devices in the active matrix array. All stretchable OTFTs in the active matrix array well operated, and transfer characteristics and statistical distribution of the electric field effect mobility thereof are shown in FIG. 37. An ideal output curve shown in FIG. 36 indicates that the Ag metallization electrode formed an ohmic contact to the DPPT-TT/SEBS nano fiber structure elastic semiconductor of the active matrix array. Electric field effect mobility and on/off ratio of the 25 OTFTs of the active matrix array were distributed as shown in FIG. 38. FIG. 39 shows that OTFT of the array exhibited low performance variability in the device electrical performance reliability evaluation result. All the transistors showed a very high reliability coefficient (>0.96) as an indicator of overestimation and miscalculation degrees of mobility (1: abnormal, 0: non-abnormal). In addition, as a result of measuring cyclic strain-stress characteristics of the active matrix array as shown in FIG. 40, the active matrix array exhibited high elasticity to 100% strain, and the active matrix array having a lower Young's modulus (0.005 MPa) than human skin (10-1 MPa) was confirmed to be attached to the skin and significantly reduce foreign body sensation. This is believed to be essential mechanical characteristics for integrating the device into human skin. Finally, the active matrix array was evaluated with respect to performance under random deformation occurring in human skin. FIG. 41 shows charge mobility changes of the active matrix array under numerous variations such as attachment to curved skin (arm), biaxial tensile strain (˜30%), and pricking with a cotton swab (depth: 1 cm). The active matrix array exhibited excellent electrical properties by well preserving the initial electric field effect mobility even under all harsh conditions. In addition, performance changes of the active matrix array according to deformation in real time are shown in FIG. 43.

Although the embodiments have been described with limited drawings as described above, various modifications and variations can be made by those skilled in the art from the above description. For example, appropriate results may be achieved even if the described techniques are performed in a different order than the described method, and/or components of the described system, structure, device, circuit, etc. are connected or combined in a different form than the described method, or they are replaced by or substituted with other components or equivalents.

Therefore, other embodiments and equivalents of the claims also fall within the scope of the following claims.

1. A semiconductor film, comprising
a stretchable semiconductor thin film comprising a first resin and a second resin, and
a noble metal layer deposited on the stretchable semiconductor thin film,
wherein the first resin includes a structural unit represented by Chemical Formula 1A and/or Chemical Formula 1B, and
the second resin includes polydimethylsiloxane, polyurethane, and/or structural units represented by Chemical Formula 2 to Chemical Formula 5: 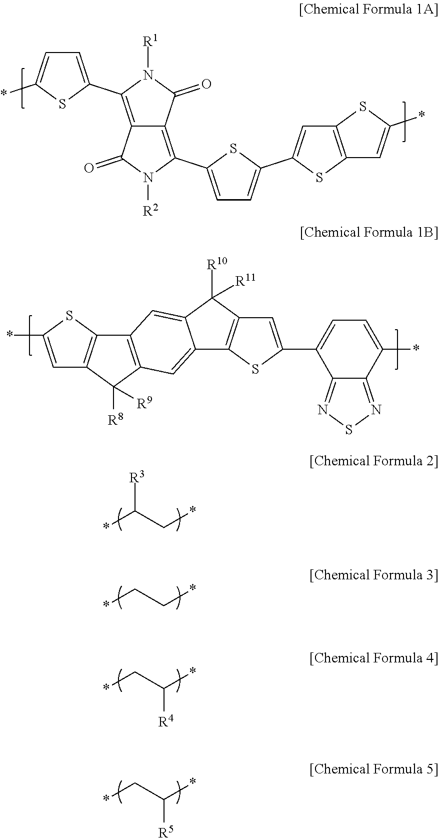
wherein, in Chemical Formula 1 Å, Chemical Formula 1B, and Chemical Formula 2 to Chemical Formula 5,
R¹, R², and R⁴ are each independently a substituted or unsubstituted C1 to C20 alkyl group,
R³ and R⁵ are each independently a substituted or unsubstituted C6 to C20 aryl group, and
R⁸ to R¹¹ are each independently a substituted or unsubstituted C11 to C20 alkyl group.

2. The semiconductor film of claim 1, wherein
R¹ and R² are the same as each other.

3. The semiconductor film of claim 1, wherein
R¹ and R² are represented by Chemical Formula 1-1: 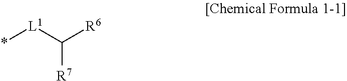
wherein, in Chemical Formula 1-1,
L¹ is a substituted or unsubstituted C1 to C20 alkylene group, and
R⁶ and R⁷ are each independently a substituted or unsubstituted C1 to C10 alkyl group.

4. The semiconductor film of claim 1, wherein
R⁸ to R¹¹ are the same as each other.

5. The semiconductor film of claim 1, wherein
R⁸ to R¹¹ are an unsubstituted C11 to C20 alkyl group.

6. The semiconductor film of claim 1, wherein
the first resin has a weight average molecular weight of greater than or equal to 100,000 g/mol.

7. The semiconductor film of claim 1, wherein
a number of moles of the structural units represented by Chemical Formula 2 and Chemical Formula 5 and a number of moles of structural units represented by Chemical Formula 3 and Chemical Formula 4 are 10 to 70:30 to 90.

8. The semiconductor film of claim 1, wherein
the noble metal includes silver (Ag).

9. The semiconductor film of claim 1, wherein
the semiconductor film further includes a noble metal oxide layer between the stretchable semiconductor thin film and the noble metal layer.

10. The semiconductor film of claim 9, wherein
a thickness of the noble metal layer is thinner than a thickness of the noble metal oxide layer, and a thickness of the noble metal oxide layer is thinner than a thickness of the stretchable semiconductor thin film.

11. A method of manufacturing a semiconductor film, comprising
preparing a stretchable semiconductor thin film including a first resin and a second resin; and
depositing a noble metal on the stretchable semiconductor thin film, wherein the deposition rate is less than or equal to 2 Å/s.

12. The method of claim 11, wherein
the first resin includes a structural unit represented by Chemical Formula 1A and/or Chemical Formula 1B, and
the second resin includes polydimethylsiloxane, polyurethane, and/or structural units represented by Chemical Formula 2 to Chemical Formula 5: 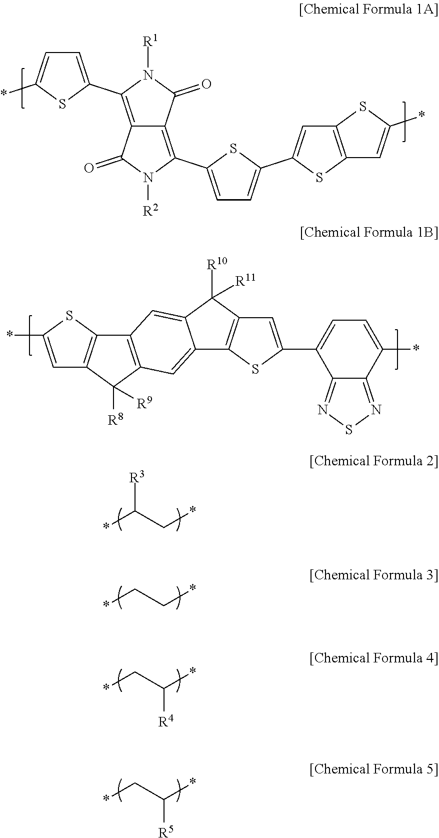
wherein, in Chemical Formula 1 Å, Chemical Formula 1B, and Chemical Formula 2 to Chemical Formula 5,
R¹, R², and R⁴ are each independently a substituted or unsubstituted C1 to C20 alkyl group,
R³ and R⁵ are each independently a substituted or unsubstituted C6 to C20 aryl group, and
R⁸ to R¹¹ are each independently a substituted or unsubstituted C11 to C20 alkyl group.

13. The method of claim 11, wherein
R¹ and R² are represented by Chemical Formula 1-1: 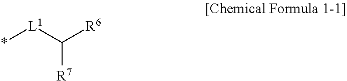
wherein, in Chemical Formula 1-1,
L¹ is a substituted or unsubstituted C1 to C20 alkylene group, and
R⁶ and R⁷ are each independently a substituted or unsubstituted C1 to C10 alkyl group.

14. The method of claim 11, wherein
R⁸ to R¹¹ are an unsubstituted C11 to C20 alkyl group.

15. The method of claim 11, wherein
the noble metal includes silver (Ag).

16. A stretchable electrode comprising the semiconductor film of claim 1.

17. The stretchable electrode of claim 16, wherein
the stretchable electrode has a thickness of less than or equal to 50 nm.

18. An organic thin film transistor comprising the stretchable electrode of claim 16.

19. An electronic device comprising the organic thin film transistor of claim 18.

20. The electronic device of claim 19, wherein
the electronic device is a wearable electronic device.
